(19) United States
(12) Patent Application Publication
(10) Pub. No.: US 2025/0264510 A1
(43) Pub. Date: Aug. 21, 2025

(54) FIRST AND SECOND MEASUREMENT DEVICE FOR TESTING A DEVICE UNDER TEST, AND A SET OF MEASUREMENT DEVICES

(71) Applicant: Rohde & Schwarz GmbH & Co. KG, Munich (DE)

(72) Inventor: Markus LANG, Ottobrunn (DE)

(21) Appl. No.: 18/442,741

(22) Filed: Feb. 15, 2024

(51) Int. Cl. G01R 27/32; G01R 13/02; G01R 23/16

(52) U.S. Cl. CPC G01R 27/32; G01R 13/02; G01R 23/16

(57) ABSTRACT

The disclosure provides a first measurement device for testing a device under test, DUT, by measuring at least one signal of the DUT, and a second measurement device for testing a device under test, DUT, by measuring at least one signal of the DUT, as well as a set of measurement devices comprising the first and second measurement device. The first measurement device comprising: at least one measurement port configured to output and/or receive a radio frequency, RF, signal to and/or from the DUT; a measurement unit connected to the at least one measurement port and being configured to measure the RF signal output and/or received at the at least one measurement port; a display unit; an user input unit for obtaining an user input; an external control interface; and a central processing unit. The second measurement device comprising: at least one measurement port configured to output and/or receive a radio frequency, RF, signal to and/or from the DUT; a measurement unit connected to the at least one measurement port and being configured to measure the RF signal output and/or received at the at least one measurement port; a central processing unit being configured to control the measurement unit; a first external control interface being configured to be connected to the external control interface of a first measurement device. The external control interface of the first measurement device being connected to the first external control interface of the second measurement device; and the central processing unit of the first measurement device being configured to receive a user input from the user input unit and to forward the user input to the central processing unit of the second measurement device.

### TECHNICAL FIELD

The present disclosure relates to measurement devices (such as a vector network analyzer, a spectrum analyzer, a signal analyzer, an oscilloscope, or the like) for testing a device under test, DUT.

Measurement devices are used in many applications today, like for example during the development of new electronic devices or for identifying errors or faults in existing devices.

### BACKGROUND ART

In general, a measurement device comprises at least one measurement port configured to output and/or receive a radio frequency, RF, signal to and/or from a DUT. Such measurement devices are currently used in the form of a vector network analyzer, VNA, a spectrum analyzer, or a signal analyzer, an oscilloscope, or the like.

However, the number of available ports per device is extremely limited due to the trade-off between available space, user operability (e.g. form of user input) and flexibility of use (e.g. integrated display for flexible “mobile” use or no display).

With regard to the special implementation of the measurement device as a VNA, it is known that several VNA devices can be connected to each other by means of a hub or in daisy chains for shared use of a synchronized common frequency sweeping signal. However, this established interconnection does not provide one VNA device to control at least one other VNA device with regard to its operation.

In general, a VNA is a reflectometer based electronic instrument that can be used to measure the frequency response (magnitude and phase) of a DUT, such as an electrical network, component, circuit, or sub-assembly. A VNA makes use of a frequency sweeping source or stimulus, directional couplers, and one or more receivers that provide ratioed amplitude and phase information such as reflection and transmission coefficients. The respective DUT is supplied with an analog input signal and reacts by generating an analog output signal. The respective input signal is provided by a measuring port of the VNA, and exemplary the analog output signal is measured by a further measuring port of the VNA. By comparing the input signal and the output signal, the scattering parameters (S-parameters) of the DUT are determined.

### SUMMARY

Thus, there is a need to provide improved measurement devices that enable a first measurement device to control operation of at least one other measurement device, e.g., of a second measurement device for improved operability of the set of measurement devices.

These and other objectives are achieved by the embodiments provided in the enclosed independent claims. Advantageous implementations of the embodiments of the present disclosure are further defined in the dependent claims. Representative embodiments are set forth in the appended claims and the following description, each of which, individually or in combination, may represent aspects of the disclosure. It should be understood that these aspects are presented merely to provide a brief summary of these certain embodiments and that these aspects are not intended to limit the scope of this disclosure. This disclosure may encompass a variety of aspects that may not be set forth below.

The terms used in the following embodiments are merely intended to describe specific embodiments, but are not intended to limit this application. As used in the specification and the appended claims of this application, the singular forms “one”, “a”, “the”, “the foregoing”, “the”, and “this” are also intended to include, for example, “one or more”, unless otherwise specified in the context.

The term “ . . . and/or . . . ” is used in the following as an equivalent of the term “at least one of . . . and . . . ”, and vice versa. The respectively used terms are thus interchangeable, and have the same meaning.

Reference to “an embodiment”, “some embodiments”, or the like described in this specification indicates that one or more embodiments of this application include a specific feature, structure, or characteristic described with reference to embodiments. Therefore, statements such as “in one embodiment”, “in some embodiments”, “in some other embodiments”, and “in still some other embodiments” that appear at different places in this specification do not necessarily refer to a same embodiment, but mean “one or more but not all embodiments”, unless otherwise specially emphasized in another manner. The terms “comprise”, “include”, “have”, and other variants thereof all mean “include but is not limited to”, unless otherwise specifically emphasized in another manner.

According to a first aspect, the present disclosure relates to a first measurement device for testing a device under test, DUT, by measuring at least one signal of the DUT. Hereby the first measurement device comprises:
at least one measurement port configured to output and/or receive a radio frequency, RF, signal to and/or from the DUT;
a measurement unit connected to the at least one measurement port and being configured to measure the RF signal output and/or received at the at least one measurement port;
a display unit;
an user input unit for obtaining an user input;
an external control interface;
a central processing unit being connected to the measurement unit, the display unit, the user input unit and the external control interface,
   whereas the central processing unit is configured:
      to receive an obtained user input from the user input unit;
      to receive the measured signal of the measurement unit; and
      to output a display signal to the display unit for displaying the received measured signal;
         wherein the central processing unit is further configured to output the user input via the external control interface to control a thereto connected device,
         wherein the second measurement device is connectable to the first measurement device via the external control interface for receiving the user input.

This achieves the advantage the first measurement device is enabled to control operation of the second measurement device via the connection established through the external control interface of the first measurement device.

In an implementation form of the first aspect, the first measurement device can be a vector network analyzer, a spectrum analyzer, or a signal analyzer, or an oscilloscope, or the like. Hereby various operation scenarios are possible that benefit from the respectively configured first measurement device that controls a thereto connected second measurement device.

In an implementation form of the first aspect, the central processing unit of the first measurement device can be configured to control the measurement unit, and in particular to adjust the measurement unit based on the obtained user input. In this case, the operation of the first measurement device itself can be adjusted according to a respective user input.

In an implementation form of the first aspect, the measurement unit can comprise measurement elements that comprise at least one of a mixer and an analog-to-digital converter, ADC (also known as analog digital converter, ADC). In this case, measurement of signals obtained or sent via the at least one measurement port is further facilitated and accuracy is further improved.

In an implementation form of the first aspect, the first measurement device can comprise a local oscillator, LO, for providing a reference signal and at least one external LO port, that is connected to the LO, for outputting the reference signal to the second measurement device. Particularly the LO can also be connected to the measurement unit, and further in particular to a mixer of the measurement unit providing the reference signal thereto. Hereby, the first measurement device may act as a signal source for the second measurement device for a respective reference signal. This further improves interoperability of the devices and further improves data acquisition and data analysis of the first and second measurement device with regard to a respectively thereto connected DUT.

In an implementation form of the first aspect, the first measurement device can comprise at least one external RF port configured to output and/or receive a RF signal to and/or from the second measurement device, and the measurement unit can be connected to the at least one external RF port and is further configured to measure the RF signal output and/or received at the at least one external RF port. In this case, the first measurement device can send and/or receive analog RF signals via the respective external RF port. For example the second measurement device can send RF signals received from a respectively thereto connected DUT via its first external control interface to the external control interface of the first management device.

In an implementation form of the first aspect, the central processing unit can be further configured to receive the measured RF signal from the measurement unit, and is further configured to send the RF signal to the display unit for displaying. In this case, a RF signal, e.g., originally originating from a DUT, measured by the second measurement device and sent to the first measurement device, where it was received via its external RF port, can be displayed via the display unit of the first management device. Also-as the user input is input via the user input unit of the first measurement device can control the operation of the second measurement device—the first measurement unit may influence the respectively received RF signal via the respectively transmitted user input.

In an implementation form of the first aspect, the measurement unit can be further configured to down-convert and digitize the RF signal received via the at least one external RF port, and send the digitized RF signal to the central processing unit. In this case, the down-convert may be realized by a mixer of the measurement unit, and the digitalization may be realized by the ADC of the measurement unit. In general a mixer is an electronic component that adds two signals to form a new signal with a frequency equal to the sum of the frequencies of the two initial signals. In the case of a vector network analyzer, the mixer can be used to mix a respective RF signal with the LO signal from a LO. The mixed product is then down-converted to an intermediate frequency, IF, suitable for further processing. In general an ADC is an electronic component that converts an analog signal into a digital signal. In the case of a measurement device, the ADC can be used to convert the mixer's mixing product into a digital signal. The resulting digital signal may then be further processed and analyzed (and potentially also displayed) by the measurement device.

In an implementation form of the first aspect, the central processing unit can be configured to apply measurement functions to the digitized RF signal, wherein the respective measurement function is selected based on the user input received from the user input unit. In this case the first measurement device is enabled to perform measurement function on the received and digitized RF signal. E.g., a signal-to-noise ratio, SNR; a peak-to-peak amplitude; a mean absolute value, MAV; a frequency; a phase; a spectral analysis; a power spectral density, PSD; or the like, of the respective RF signal may be measured. Of course other measurement functions are equally conceivable.

In an implementation form of the first aspect, the external control interface further can be configured for receiving a digitized external data signal from the second measurement device, whereas the digitized external data signal comprises a digitized RF signal. Alternatively or additionally the first measurement device can comprise an external data interface for receiving a digitized external data signal, whereas the digitized external data signal comprises a digitized RF signal, wherein the central processing unit is connected to the external data interface, and wherein the second measurement device is further connectable to the first measurement device via the external data interface for transmitting the digitized external data signal. In both cases the central processing unit can further be configured to receive the digitized external data signal from the second measurement device via at least one of the external control interface and the external data interface. In these scenarios, the first measurement device can receive digital signals from the second measurement device, such that the steps of digitizing a received RF signal are not necessary.

In an implementation form of the first aspect, the central processing unit can be configured to send the digitized RF signal to the display unit for displaying. In this case, a RF signal, e.g., originally originating from a DUT, was measured and digitized by the second measurement device and sent to the first measurement device, where it was received, e.g., via at least one of the external control interface and the external data interface, can be displayed via the display unit of the first management device.

According to a second aspect, the present disclosure relates to a second measurement device for testing a device under test, DUT, by measuring at least one signal of the DUT. Hereby the second measurement device comprises:
at least one measurement port configured to output and/or receive a radio frequency, RF, signal to and/or from the DUT;
a measurement unit connected to the at least one measurement port and being configured to measure the RF signal output and/or received at the at least one measurement port;
a central processing unit being configured to control the measurement unit;
a first external control interface being configured to be connected to the external control interface of a first measurement device;
   the central processing unit being configured to receive a user input from the first external control interface and to control the measurement unit based on the received user input.

This achieves the advantage the second measurement device being controllable by the first measurement device via the connection established through the external control interface of the first measurement device.

In an implementation form of the second aspect, the second measurement device being a vector network analyzer, a spectrum analyzer, a signal analyzer or an oscilloscope, or the like. Hereby, the second measurement device may correspond to the type of the first measurement device in order to further improve the functionality of the system with the respective measuring devices.

In an implementation form of the second aspect, the central processing unit of the second measurement device being configured to adjust the measurement unit based on the received user input. In this case, the central processing unit of the second measurement device not only controls the operation of the respective measurement unit but can also adjust parameters thereof. This further improves interoperability and facilitates operation of the set of first and second measurement device.

In an implementation form of the second aspect, the second measurement device comprising at least one first external local oscillator, LO, port for receiving a reference signal, such as an LO signal, from an external LO port of the first measurement device. In this case, the second measurement device is enabled to use the same LO signal as the first measurement device, which further links the two measurement devices and further improves consistent measurement of respective signals. Furthermore, comparability of the signals measured by the first and second measurement device is further increased.

In an implementation form of the second aspect, the second measurement device comprising at least one first external RF port configured to receive and/or output a RF signal from or to the first measurement device, wherein the measurement unit is connected to the at least one external RF port and is further configured to measure the RF signal output and/or received at the at least one external RF port. In this case the connection between the second measurement device and the first measurement device and interoperability of these devices is further improved.

In an implementation form of the second aspect, the measurement unit being configured to down-convert and digitize the RF signal received via the at least one measurement port. In this case, the down-convert may be realized by a mixer of the measurement unit, and the digitalization may be realized by the ADC of the measurement unit.

In an implementation form of the second aspect, the central processing unit being configured to output:
a) the RF signal received via the at least one measurement port via the at least one first external RF port to the first measurement device; and/or
b) the digitized RF signal via the first external control interface or via a first external data interface of the second measurement device to the first measurement device.
   In each of these cases signal transmission towards the first measurement device is achieved, such that measured signals of the DUT are provided towards the first measurement device.

It is also conceivable that a second external data interface is provided at the second measurement device to allow for further second measurement devices (i.e., “third”, “fourth”, . . . measurement device) being connected in a daisy-chain manner. Hereby it is to be stated that the features disclosed herein concerning the second measurement device are also applicable with regard to these other further measurement devices.

In an implementation form of the second aspect, the second measurement device comprises a second external control interface configured for daisy-chaining the first external control interface with the second external control interface, wherein a third measurement device is connectable to the second external control interface. In this case, further measurement devices can be connected in daisy chain, further ultimately improving the number of measurement ports controlled by the first measurement device.

In an implementation form of the second aspect, the second measurement device comprises a second LO port for daisy-chaining the first LO port to the second LO port, wherein a third measurement device is connectable the second LO port. In this case, interoperability between the individual measurement devices is further improved.

In an implementation form of the second aspect, the second measurement device comprises a second external RF port for daisy-chaining the first external RF port to the second external RF port, wherein a third measurement device is connectable the second external RF port. In this case, interoperability between the individual measurement devices is further improved.

In an implementation form of the second aspect, the second measurement device comprises a second external data interface configured for daisy-chaining the first external data interface with the second external data interface, wherein a third measurement device is connectable to the second external data interface. In this case, further measurement devices can be connected in daisy chain, further ultimately improving the number of measurement ports controlled by the first measurement device.

According to a third aspect, the present disclosure relates to a set of measurement devices comprising a first measurement device and a second measurement device. Hereby, the external control interface of the first measurement device can be connected to the first external control interface of the second measurement device; and the central processing unit of the first measurement device being configured to receive a user input from the user input unit and to forward the user input to the central processing unit of the second measurement device.

This achieves the advantage of the improved interoperability between the first and the second measurement device, with the first measurement device being able to control the second measurement device via the established connection.

In an implementation form of the first, second or third aspect, the connection between the first and second measurement device is substantially free of latency, and provides an utmost fast data transmission. In this case, e.g., the interconnection may be realized by terms of an optical data transmission system (e.g., via fiber optics, or via laser beam communication, or the like), or via a direct data transmission system (e.g., via a wired transmission system, or via a backplane data transmission system, or the like).

For reasons of brevity, features of a measurement device described below in the specific exemplary implementation of a VNA are also valid and applicable with regard to other implementations of the measurement device.

Still other aspects, features, and advantages of the present invention are readily apparent from the following detailed description, simply by illustrating a number of particular embodiments and implementations, including the best mode contemplated for carrying out the present invention. The present invention is also capable of other and different embodiments, and its several details can be modified in various obvious respects, all without departing from the spirit and scope of the present invention. Accordingly, the drawing and description are to be regarded as illustrative in nature, and not as restrictive.

### BRIEF DESCRIPTION OF THE DRAWINGS

The above described aspects and implementation forms of the present disclosure will be explained in the following description of specific embodiments in relation to the enclosed drawings, in which:

FIG. 1 shows a schematic illustration of a first measurement device according to an embodiment, and a second measurement device according to an embodiment, the two measurement devices forming a set of measurement devices according to an embodiment;

FIG. 2 shows a schematic diagram of a first measurement device according to an embodiment;

FIG. 3 shows a schematic diagram of a first measurement device according to an other embodiment;

FIG. 4 shows a schematic diagram of a second measurement device according to an embodiment;

FIG. 5 shows a schematic diagram of a second measurement device according to an other embodiment;

FIG. 6 shows a schematic diagram of a set of measurement devices according to an other embodiment, whereas the set comprises a first measurement device according to an embodiment, a second measurement device according to an embodiment and a third measurement device according to an embodiment.

### DETAILED DESCRIPTIONS OF EMBODIMENTS

FIG. 1 shows a schematic diagram of a first measurement device 100 according to an embodiment, and a second measurement device 200 according to an embodiment, the two measurement devices 100, 200 forming a set 10 of measurement devices according to an embodiment. These two measurement devices 100, 200 hereby form an exemplary embodiment of a set of measurement devices.

The first measurement device 100 hereby is illustrated as a benchtop device (or tabletop device), and usually is implemented as a vector network analyzer, a spectrum analyzer, or a signal analyzer, an oscilloscope, or the like. Such a measurement device is connected to a device under test, DUT, 400 in order to test the device and its behavior in certain scenarios.

In FIG. 1 the first measurement device 100 is sketched as a vector network analyzer, VNA, that comprises a display unit 130, and user input unit 140 and various interfaces 190. Hereby, the first measurement device 100 comprises measurement ports 196, that each are configured to output and/or receive a radio frequency, RF, signal to and/or from the DUT 400, whereas the DUT 400 is connected to a respective measurement port 196 of the first measurement device 100 via a testing transmission 500, which can be a common testing cable 500.

A user of the first measurement device 100 can input via the user input unit 140 certain controls to adjust a respective testing of the DUT 400. E.g., test signals being output to the DUT 400 via the respective measurement ports 196 can be controlled and signals received from the DUT 400 can be individually processed as well. Thus, with such a configuration and the user input unit 140 at hand a user can specifically adjust a certain testing scenario of the DUT 400. Further, the user can spectate the received signals from the DUT 400—as well as the signals sent thereto—via the display unit 130. Therefore, with the such configured first measurement device 100 extra peripheral devices such as user input devices (e.g., a keyboard, a computer mouse, or the like) and display devices (e.g., a monitor, or the like) are not necessary for operation of the first measurement device 100. This further increases flexibility of operation of the first measurement device 100.

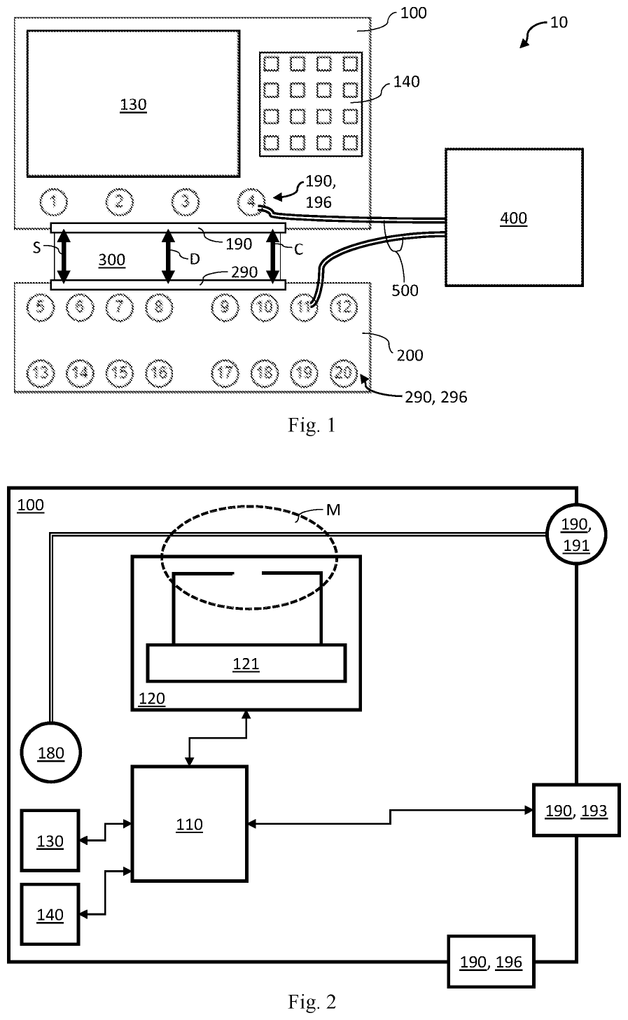

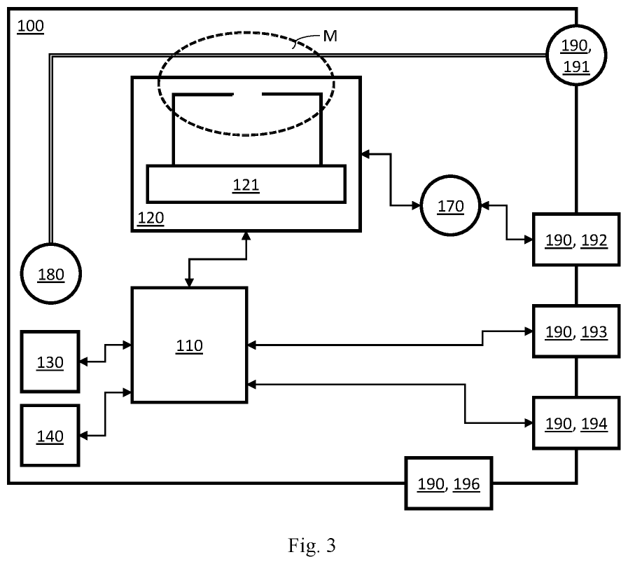

FIGS. 2 and 3 show different exemplary embodiments of a first measurement device 100, whereas the different embodiments differ with regard to the components of the respective first measurement device 100.

The first measurement device 100 of FIG. 2 comprises several ports 190, a central processing unit 110, a measurement unit 120, a signal source 180, as well as a display unit 130 and a user input unit 140. The several ports 190 hereby have at least one measurement port 196, that configured to output and/or receive a RF signal to and/or from the DUT 400 (the DUT 400, as well as external connections 300, 500 are not shown in FIGS. 2 to 5 for simplicity reasons), an external control interface 193, and an external RF port 191. The central processing unit 110 is connected to the measurement unit 120, the display unit 130, the user input unit 140 and the external control interface 193, and hereby interacts with each of these components. The measurement unit 120 is connected to the at least one measurement port 196 (not shown in the schematic Figures), and in the present embodiment it is also connected to the external RF port 191, and hereby is configured to measure M a respective RF signal output and/or received by the respectively connected ports 190. Measurement M is hereby performed by the measurement unit 220 in a certain measurement region M, where the measurement unit 220—respectively its measurement elements 210—are in close vicinity to the respective to be observed measurement path (as schematically indicated in the Figures).

In particular the central processing unit 110 is configured: to receive an obtained user input from the user input unit 140; to receive a respectively measured M signal of the measurement unit 120; and to output a display signal to the display unit 130 for displaying the received measured signal. Thus, the first measurement device 100 is configured to send specific testing signals to a DUT 400, measure the corresponding response signals sent from the DUT 400 to the first measurement device 100 and display these accordingly. Moreover, the central processing unit 110 is configured to output the obtained user input via the external control interface 193 to control a respectively thereto connected device—such as the second measurement device 200—, as the second measurement device 200 is connectable to the first measurement device 100 via the external control interface 193 for receiving the user input. Thus, with this implementation the user input that is input at the first measurement device 100 is used control the second measurement device 200.

Moreover, in the shown embodiment the central processing unit of the first measurement device 100 is further configured to control the measurement unit 120, and in particular to adjust the measurement unit 120 based on the obtained user input. Thus, e.g., fine-tuning of measurement parameters is possible, which allows operation of the first measurement device 100 in various scenarios. Also, with regard to measured M signals received from and/or sent to the second measurement device 200 it is to be noted that this configuration further improves interoperability and facilitates operation of the set of first and second measurement device 100, 200.

As shown in FIG. 2 the shown embodiment of the first measurement device 100 also comprises (at least) one external RF port 191 that is configured to output and/or receive a RF signal to and/or from the second measurement device 200, wherein the measurement unit 120 is connected to the at least one external RF port 191 for measurement M. Thus the measurement unit 120 is further configured to measure the RF signal output and/or received at the external RF port 191, and send the respective measured M signal to the central processing unit 110. The central processing unit 110 is therefore configured to receive the measured RF signal from the measurement unit 120, and is further configured to send the RF signal to the display unit 130 for displaying.

The external RF port 191 is connected to the signal source 180. The signal source 180 may be a signal source for a continuous wave, cw, signal that is used for certain measurement functions, and may hereby be output, e.g., via the external RF port 191 to the second measurement device 200, or the like. Furthermore, the external RF port 191 may be used for receiving (analog) RF signals, e.g., from the second measurement device 200. These signals are then measured M by the measurement unit 120 of the first measurement device 100. In the shown exemplary embodiment only one measurement path is indicated, whereas of course it is conceivable that more than one measurement path is present, whereas each measurement path can be individually measured M by the measurement unit 120. The measurement unit 120 comprises measurement elements 121, such as, e.g., a mixer and/or an analog digital converter, ADC.

Although not explicitly shown in FIG. 2 in the embodiment at least one measurement port 196 is observed by the measurement unit 120 of the of the first measurement device 100, such that analog RF signals received from the respective DUT 400 are also measured M. Hereby, the measurement unit 120 is configured to down-convert and digitize a respective detected RF signal received via the at least one external RF port 191 (and/or potentially the at least one measurement port 196), and send the digitized RF signal to the central processing unit 110. Hereby the down-convert may be realized by a mixer of the measurement unit 120, and the digitalization may be realized by the ADC of the measurement unit 120.

In general a mixer is an electronic component that adds two signals to form a new signal with a frequency equal to the sum of the frequencies of the two initial signals. For instance the mixer can be used to mix a respective RF signal with a LO signal from a LO 170, 270. The mixed product is then down-converted to an intermediate frequency, IF, suitable for further processing. An ADC is an electronic component that converts an analog signal into a digital signal. Within a measurement device, the ADC can be used to convert the mixer's mixing product into a digital signal. The resulting digital signal may then be further processed and analyzed (and potentially also displayed) by and within the respective measurement device.

In the shown embodiment, the central processing unit 110 is also configured to apply measurement functions to the respective digitized RF signal, whereas the measurement function is selected based on the respective user input received from the user input unit 140.

In the shown embodiment of FIG. 2 the external control interface 193 is further configured for receiving a digitized external data signal from the second measurement device 200, whereas the digitized external data signal D comprises a digitized RF signal. Thus, the control signal C communication line can be also used to transmit data signals D. The received digitized data signal D is thus made available for the central processing unit 110 due to the connection between the external control interface 193 and the central processing unit 110. This form of communication can be additionally or alternatively used over the direct transmission of RF signals to the external RF port 191 of the first measurement device 100 from the second measurement device 200.

As further shown in the other exemplary embodiment of the first measurement device 100 of FIG. 3 the first measurement device 100 can also comprise a local oscillator, LO, 170 for providing a reference signal. The LO 170 usually is implemented as an electronic oscillator that generates a high-frequency signal (i.e., a LO signal) that can be used, e.g., as a reference signal in electronic circuits. As further shown in FIG. 3 the first measurement device 100 further comprises (at least) one external LO port 192 that is connected to the LO 170 for outputting the reference signal (respectively the LO signal) to the second measurement device 200. The LO 170 hereby may be configured to generate a stable, continuous sine wave. This LO signal is hereby also made available to the measurement unit 120, and in particular to the mixer of the measurement unit 120.

The exemplary embodiment of FIG. 3 of the first measurement device 100 further comprises (at least) one external data interface 194 for receiving a digitized external data signal, whereas the digitized external data signal comprises a digitized RF signal. Hereby the central processing unit 110 is connected to the external data interface 194. Also the second measurement device 200 is connectable to the first measurement device 100 via the external data interface 194 for transmitting the digitized external data signal. This external data interface 194 is thus configured for communication of data D in-between the first measurement device 100 and the second measurement device 200.

As previously discussed with regard to the external control interface 193 of the embodiment shown in FIG. 2 and its capability of receiving digitized signals, the extra external data interface 194 of the first measurement device 100 of FIG. 3 so to say undertakes this task—while it is also conceivable that the external control interface 193 remains capable of such a receival and/or transmission. Thus, the central processing unit 110 of the shown embodiment of FIG. 3 is configured to receive the digitized external data signal from the second measurement device 200 via at least one of the external control interface 193 and the external data interface 194.

In either embodiment of FIGS. 2 and 3 the central processing unit 110 is configured to send the respective digitized RF signal to the display unit 130 for displaying.

As further perceptible from FIG. 1 space is limited on and in a measurement device in general and due to the components as user input unit 140 and display unit 130 and the thereto related electronic components on-and inside the housing of the first measurement device 100 only a limited number of measurement ports 196 are available. In the present exemplary embodiment, four measurement ports 196 are present at the first measurement device 100.

To further increase the maximum number of measurement ports 196, 296 available for the first measurement device 100 a second measurement device 200 is connected to the first measurement device 100, whereas the first measurement device 100 controls the second measurement device 200—and in a specific embodiment the measurement unit 210 of the second measurement device 200—according to a respective user input obtained via the user input unit 140. Hereby the first measurement device 100 is configured to output the obtained user input to the second measurement device 200.

The second measurement device 200 is-equally to the first measurement device 100—illustrated as a benchtop device (or tabletop device), and is also usually implemented as a VNA, a spectrum analyzer, or a signal analyzer, an oscilloscope, or the like. For simplicity reasons the second measurement device 200 is sketched as a VNA as well, whereas in this exemplary embodiment the second measurement device 200 comprises various interfaces 290 but no display unit and no user input unit, and thus is realized as a so called faceless device. However, it is conceivable that the second measurement device 200 also comprises at least a small display unit for, e.g., direct illustration of measured signals.

The measurement ports 296 of the second measurement device 200 can each be connected to a respective DUT 400 to send and/or receive signals thereto/therefrom. In the shown exemplary embodiment the second measurement device 200 is connected via a testing transmission 500, which may be a common testing cable 500, to the DUT 400.

In the exemplary embodiment shown in FIG. 1 the second measurement device 200 comprises twelve measurement ports 296. As explained herein, with the established connection between the first and second measurement devices 100, 200 the measurement ports 296 of the second measurement device 200 can be made available to the first measurement unit 100, such that the first measurement unit 100 can access a total number of sixteen ports (in the shown example). By adding a third measurement device 200x to the set 10, this number of available measurement ports 196, 296 can be further increased.

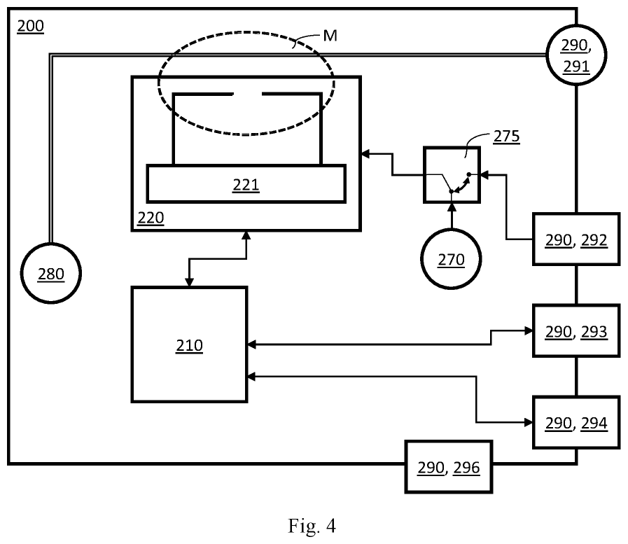

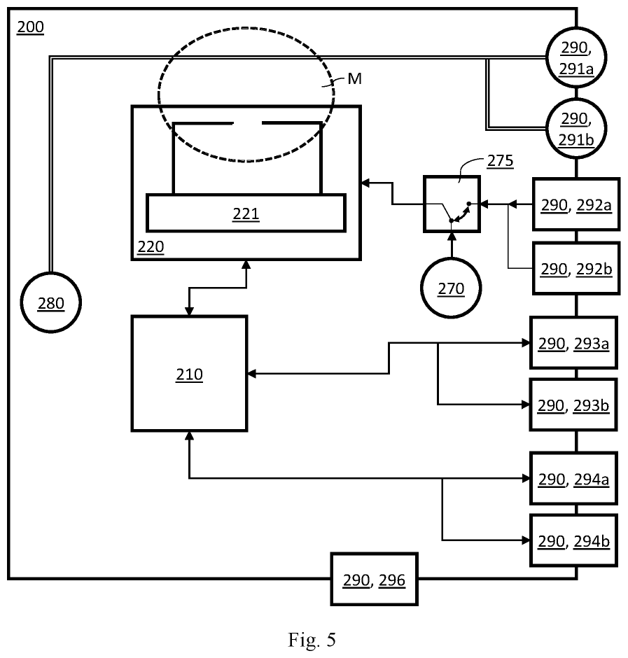

The FIGS. 4 and 5 show different exemplary embodiments of such a second measurement device 200. In general, elements that are present in both the first and second measurement device 100, 200 have similar or identical characteristics, unless explicitly stated otherwise. In this respect, the description of these features are interchangeable.

With regard to FIG. 4 it is already apparent that the principle set up of the second measurement device 200 is similar to the setup of the first measurement device 100, as also the second measurement device 200 is configured for testing a DUT by measuring at least one signal of the DUT. Hereby the second measurement device 200 comprises: at least one measurement port 296 configured to output and/or receive a RF signal to and/or from the DUT; a measurement unit 220 connected to the at least one measurement port 296 (not shown in the schematic Figures) and being configured to measure the RF signal output and/or received at the at least one measurement port 296; and a central processing unit 210 being configured to control the measurement unit 220.

Clearly the second measurement device 200 does not comprise a user input unit, whereas the second measurement device 200 comprises a first external control interface 293, 293a that is configured to be connected to the external control interface 193 of a first measurement device 100. Through this component the second measurement device 200 is thus enabled to receive signals from the first measurement device 100, whereas these signals comprise control signals C that at least include a respectively forwarded user input that was previously input at the user input unit 140 of the first measurement device 100. The central processing unit 210 of the second measurement device 200 on the other hand is configured to receive the respective user input from the first external control interface 293, 293a and to control the measurement unit 220 based on the received user input. Thus, so to say the second measurement device 200—and in particular the central processing unit 210 and the measurement unit 220 thereof—is controlled by the first measurement device 100 by outputting a respective user input via the external control interface 193 to control the thereto connected second measurement device 200.

In the shown exemplary embodiment of FIG. 4 the second measurement device 200 also comprises a LO 270 itself that may generate an own reference signal (respectively LO signal) for the second measurement device 200. However, in an other potential embodiment an own LO 270 is not necessary, with a first external LO port 292, 292a being provided with the second measurement unit 200. This first external LO port 292, 292a is configured for receiving an LO signal (i.e., a reference signal) from an external LO port 192 of the first measurement device 100. In the shown embodiment both a first external LO port 292, 292a and a LO 270 are present in the spectated second measurement device 200. Hereby a switch 275 is additionally provided, whereas the switch 275 may be directly controlled by the central processing unit 210 of the second measurement device 200—potentially executing a respective control received from a provided user input received from the first measurement device 100. The switch 275 hereby selects whether the external LO signal or the LO signal of the own LO 270 is used within the second measurement device 200 for operation. The respectively selected LO signal is then made available at the measurement unit 220.

As illustrated in the Figures the LO signal of the second measurement device 200 is not made available to other measurement devices, i.e. the LO signal of the LO 270 of the second measurement device 200 is not output via the first external LO port 292, 292a—the first external LO port 292, 292a is thus configured for receiving a reference signal from an external LO port 192 of the first measurement device 100.

Furthermore, in the presented exemplary embodiment of FIG. 4 the second measurement device 200 also comprises at least one first external RF port 291, 291a configured to receive and/or output a RF signal from or to the first measurement device 100, wherein the measurement unit 220 is connected to the at least one external RF port 291, 291a and is further configured to measure the RF signal output and/or received at the at least one external RF port 291, 291a.

In the shown embodiment solely one measurement path is shown whereas of course more than one measurement paths are conceivable. Each measurement path (also the measurement path(s) relating to the measurement ports 296 of the second measurement device) can be individually measured M by the measurement unit 220.

The external RF port 291, 291a may thus be used for communication purposes with the first measurement device 100 and in particular to transmit RF signals comprising information, e.g., about the RF signals received from a respective connected DUT 400.

Similarly to what was previously described concerning the first measurement device 100 the RF signals obtained (and/or sent) from (or to) the respective DUT 400 are also measured M by the measurement unit 220 of the second measurement device 200.

In the shown embodiment the central processing unit 210 of the second measurement device 200 is further configured to adjust the measurement unit 220 based on the received user input. Thus, the measurement M of the second measurement device 200 can be fine-tuned and adapted to a respective present scenario by the user via a respective input at the user input unit 140 of the first measurement device 100.

The measurement unit 220 may configured analogously to the measurement unit 120 of the first measurement device 100. Thus, the measurement unit 220 of the second measurement device may also comprise measurement elements 121, such as, e.g., a mixer and/or an analog digital converter, ADC.

Analog to what is already described with regard to the first measurement device 100, a measurement path of the second measurement device 200 may also be connected to a signal source 280 of the second measurement device 200, whereas the signal source 280 may provide a continuous wave, cw, signal on the respective measurement path.

Similar to the configuration of the first measurement device 100 the second measurement device 200 may also comprise a first external data interface 294, 294a, as shown in FIG. 4. Via this first external data interface 294, 294a, that is connected to the external data interface 194 of the first measurement device 100 in the combined setup of the first and second measurement unit 100, 200, data signal D communication is established via an distinct line of communication. If such a first external data interface 294, 294a is not present, data signal D communication can also be established via the first external RF port 291, 291a of the second measurement device 200 and the external RF port 191 of the first measurement device 100, or alternatively or additionally via the first external control interface 293, 293a of the second measurement device 200 and the external control interface 193 of the first measurement device 100—as previously described.

In the shown example the measurement unit 220 is further configured to down-convert and digitize a respective RF signal received via the at least one measurement port 296 or the first external RF port 291, 291a. Thus, this applies likewise to measured signals originating from a respective DUT 400 as well as signals originating from the first measurement device 100, whereas the first scenario is more relevant. Therefore, the originally obtained analogue RF signal, received at the measurement port 296 (or the first external RF port 291, 291a) is digitalized by the measurement unit 220. With the measurement unit 220 being connected to the central processing unit 210 the measured signal, respectively the digitalized signal, is made available to the central processing unit 210.

The measured M signal measured by the second measurement device 200 can then be transmitted to the first measurement device 100, depending on the present components of the respective embodiment of the second measurement device 200. Hereby it is conceivable that the central processing unit 210 of the second measurement device 200 is configured to output the analog RF signal received via the at least one measurement port 296 via the at least one first external RF port 291, 291a to the first measurement device 100. Alternatively or additionally it is also conceivable that the central processing unit 210 is configured to output the respective digitized RF signal via the first external control interface 293, 293a of the second measurement device 200 to the first measurement device 100. With a first external data interface 194 being present, it is also alternatively or additionally conceivable that the central processing unit 210 is configured to output the respective digitized RF signal via the first external data interface 294, 294a of the second measurement device 200 to the first measurement device 100.

FIG. 5 shows an other exemplary embodiment of the second measurement device 200. The functionality of this second measurement device 200 is hereby basically analog to the second measurement device 200 previously discussed. However, it is clearly visible that the number of ports 290 available increased in this embodiment, as the herein presented second measurement device 200 now comprises a second external control interface 293b, second external data interface 294b, a second LO port 292b, and also a second external RF port 291b. The respective second ports/interfaces 29*b are analogously connected to other components of the respective second measurement device 200 as the respective corresponding first port 29*a.

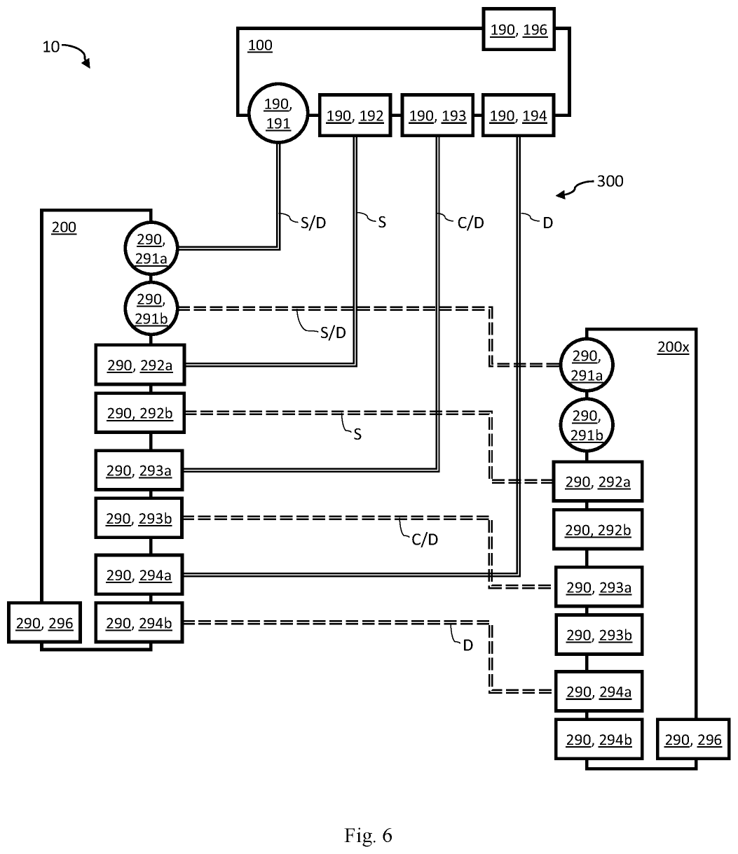

Hereby the second external control interface 293b configured for daisy-chaining the first external control interface 293, 293a with the second external control interface 293b, such that signals present at the first external control interface 293, 293a are also available at the second external control interface 293b, and vice versa. With this configuration a third measurement device 200x is connectable to the second external control interface 293b of the second measurement device 200. This is also indicated in the illustration of the set 10 of measurement devices shown in FIG. 6.

Therefore, the such connected third measurement device 200x also is controllable by the first measurement device 100 as the user input output via the external control interface 193 of the first measurement device 100 also reaches the third measurement device 200x. The embodiments and features shown and described with regard to the second measurement device 200 are equally valid with regard to the third measurement device 200x.

The other second ports 29*b are analogously configured, to allow daisy chaining of the respective first port 29*a. Thus, in the shown embodiment of the second measurement device 200 the second external data interface 294b is configured for daisy-chaining the first external data 294, 294a interface with the second external data interface 294b, wherein a third measurement device 200x is connectable to the second external data interface 294b. Likewise, the second LO port 292b is configured for daisy-chaining the first LO port 292, 292a to the second LO port 292b, wherein a third measurement device 200x is connectable the second LO port 292b. Further, the second external RF port 291b is configured for daisy-chaining the first external RF port 291, 291a to the second external RF port 291b, wherein a third measurement device 200x is connectable the second external RF port.

It is further conceivable that a set 10 of measurement devices comprises even more measurement devices 100, 200, 200x, . . . , whereas a respective fourth measurement device is connected in daisy chain with the third measurement device 200x and so forth.

FIG. 6 shows an exemplary setup of a respective set 10 of measurement devices. Hereby, a second and a third measurement device 200, 200x are connected in daisy chain to the respective ports of the first measurement device 100. Hereby data signals D, control signals C and other signals S are shared to and from the individual measurement devices 100, 200, 200x, as previously described.

Thus, the external control interface 193 of the first measurement device 100 is connected to the first external control interface 293, 293a of the second measurement device 200, and the central processing unit 110 of the first measurement device 100 is configured to receive a user input from the user input unit 140 and to forward the user input to the central processing unit 210 of the second measurement device 200. With the third measurement device 200x being connected, this is analogously continued.

This setup allows the first measurement device 100, which usually is limited to a low number of measurement ports 196 for measuring/testing respective devices under test 400, to make use of the additional measurement ports 296 provided by respective connected second (, third, fourth, . . . ) measurement devices 200, 200x, . . . , whereas control of the connected further measurement devices 200, 200x is performed and achieved via the first measurement device 100. The first measurement device 100, and in particular its central processing unit 110, is hereby configured to process the received signals of the further measurement devices 200, 200x as if these signals would have been obtained by its own measurement ports 196, whereas furthermore the respective signals can also be displayed on the display unit 130 of the first measurement device 100.

In combined view of the disclosures of FIG. 6 and FIG. 1, it is noted that the several (additional) measurement ports 296 of the second (and third) measurement device(s) 200, 200x are accessible—at least for control via the control signals S provided via the external control interface 193, 293a, 293b—to the first measurement device 100 via a respective communication link 300. Hereby control signals C are transmitted between the first measurement device 100 and the second measurement device 200 (and a potential third measurement device 200x) that include respective control information of a particular user input obtained by the first measurement device 100 via its user input unit 140. In the shown embodiment, also transmission of data signals D and other signals S in-between the first and second measurement device 100, 200 (and potential also third measurement device 200x and further other measurement devices) are present. Data signals D sent from the second measurement device 200 to the first measurement device 100 may hereby include analog and/or digital signals that include data concerning a respectively tested DUT 400. The other transmitted signals S may further comprise a reference signal, such as a LO signal generated by a LO 170 of the first measurement device 100.

With the transmission of such data, control and other signals D, C, S the second measurement device 200 acts as an extension of the first measurement device 100 as its ports 290 and the resulting measurements concerning a respective DUT 400 are available to the first measurement device 100 as if these would be its own ports 190 resulting from the close coupling of these two measurement devices 100, 200. This is equally valid with regard to a set 10 of measurement devices consisting of more than two measurement devices.

The two coupled measurement devices 100, 200 shown in FIG. 1 as well as the three coupled measurement devices 100, 200, 200x of FIG. 6 thus each form a set 10 of measurement devices. The set 10 therefore appears to be a single measurement device for a user, as the first and second measurement devices 100, 200 (and potentially third measurement device 200x) are thus interconnected with one another and therefore provide a seamless integration of the additional ports 290 of the further measurement devices 200, 200x to the first measurement device 100 in the shown embodiments.

Various implementations of the communication links 300 in-between the first and second measurement device 100, 200 are conceivable, whereas it is desired that the communication is substantially latency free and provides an utmost fast data rates. Thus, different types of communication systems may be implemented for the different signal S, D, C transmissions. Exemplary, an optical data transmission (e.g., via fiber optics, or via laser beam communication, or the like), or a direct data transmission (e.g., via a wired transmission system, or via a backplane data transmission system, or the like) is conceivable.

The first and second measurement devices 100, 200 (see FIG. 1), as well as the first, second and third measurement devices 100, 200, 200x are connected together via a respective transmission 300, whereas control signals C, data signals D, and/or other signals S can be transmitted between the first measurement device 100 and the respectively provided further measurement devices 200, 200x.

In general, measurement M of a signal on a measurement path of the first, second, third, . . . measurement device 100, 200, 200x, . . . may take place via a sync interface, preferably as a direct interface between ASICs and/or FPGAs of the respective measurement device 100, 200, 200x.

Furthermore it is conceivable that multiple different DUT 400 are connected to one measurement device 100, 200, 200x or one set 10 of measurement devices, such that various measurements of different DUT 400 can be performed simultaneously.

Overall, with the presented disclosure a combination of the advantages of faceless measurement devices with their small space requirement and high number of available ports, and the advantages of benchtop devices with their good operability on the device itself, is achieved.

All features described above or features shown in the figures can be combined with each other in any advantageous manner within the scope of the disclosure. Features mentioned with regard to the first measurement device 100 and/or the second (or third) measurement devices 200, 200x are also valid with regard to a respective set 10 of measurement devices.

1. A first measurement device for testing a device under test, DUT, by measuring at least one signal of the DUT, the first measurement device comprising:
at least one measurement port configured to output and/or receive a radio frequency, RF, signal to and/or from the DUT;
a measurement unit connected to the at least one measurement port and being configured to measure the RF signal output and/or received at the at least one measurement port;
a display unit;
an user input unit for obtaining an user input;
an external control interface;
a central processing unit being connected to the measurement unit, the display unit, the user input unit and the external control interface,
whereas the central processing unit is configured:
to receive an obtained user input from the user input unit;
to receive the measured signal of the measurement unit; and
to output a display signal to the display unit for displaying the received measured signal;
wherein the central processing unit is further configured to output the user input via the external control interface to control a thereto connected device,
wherein a second measurement device is connectable to the first measurement device via the external control interface for receiving the user input.

2. The first measurement device according to claim 1,
the first measurement device being a vector network analyzer, a spectrum analyzer, or a signal analyzer, or an oscilloscope.

3. The first measurement device according to claim 1,
the central processing unit of the first measurement device being configured to control the measurement unit, and in particular to adjust the measurement unit based on the obtained user input.

4. The first measurement device according to claim 1,
the measurement unit comprising measurement elements, that comprise at least one of a mixer and an analog digital converter, ADC.

5. The first measurement device according to claim 1,
the first measurement device comprising a local oscillator, LO, for providing a reference signal and at least one external LO port, that is connected to the LO, for outputting the reference signal to the second measurement device,
wherein in particularly the LO being also connected to the measurement unit, and further in particular to a mixer of the measurement unit providing the reference signal thereto.

6. The first measurement device according to claim 1,
the first measurement device comprising at least one external RF port configured to output and/or receive a RF signal to and/or from the second measurement device,
wherein the measurement unit is connected to the at least one external RF port and is further configured to measure the RF signal output and/or received at the at least one external RF port.

7. The first measurement device according to claim 6,
the central processing unit being configured to receive the measured RF signal from the measurement unit, and is further configured to send the RF signal to the display unit for displaying.

8. The first measurement device according to claim 6,
the measurement unit being configured to down-convert and digitize the RF signal received via the at least one external RF port, and send the digitized RF signal to the central processing unit.

9. The first measurement device according to claim 8,
the central processing unit being configured to apply measurement functions to the digitized RF signal, wherein the respective measurement function is selected based on the user input received from the user input unit.

10. The first measurement device according to claim 1,
the external control interface further being configured for receiving a digitized external data signal from the second measurement device, whereas the digitized external data signal comprises a digitized RF signal, and/or
the first measurement device comprising an external data interface for receiving a digitized external data signal, whereas the digitized external data signal comprises a digitized RF signal, wherein the central processing unit is connected to the external data interface, and wherein the second measurement device is further connectable to the first measurement device via the external data interface for transmitting the digitized external data signal;
wherein the central processing unit is further configured to receive the digitized external data signal from the second measurement device via at least one of the external control interface and the external data interface.

11. The first measurement device according to claim 10,
the central processing unit being configured to send the digitized RF signal to the display unit for displaying.

12. A second measurement device for testing a device under test, DUT, by measuring at least one signal of the DUT, the second measurement device comprising:
at least one measurement port configured to output and/or receive a radio frequency, RF, signal to and/or from the DUT;
a measurement unit connected to the at least one measurement port and being configured to measure the RF signal output and/or received at the at least one measurement port;
a central processing unit being configured to control the measurement unit;
a first external control interface being configured to be connected to the external control interface of a first measurement device;
the central processing unit being configured to receive a user input from the first external control interface and to control the measurement unit based on the received user input.

13. The second measurement device according to claim 12,
the second measurement device being a vector network analyzer, a spectrum analyzer, a signal analyzer or an oscilloscope.

14. The second measurement device according to claim 12,
the central processing unit of the second measurement device being configured to adjust the measurement unit based on the received user input.

15. The second measurement device according to claim 12,
the second measurement device comprising at least one first external local oscillator, LO, port for receiving a reference signal from an external LO port of the first measurement device.

16. The second measurement device according to claim 12,
the second measurement device comprising at least one first external RF port configured to receive and/or output a RF signal from or to the first measurement device,
wherein the measurement unit is connected to the at least one external RF port and is further configured to measure the RF signal output and/or received at the at least one external RF port.

17. The second measurement device according to claim 12,
the measurement unit being configured to down-convert and digitize the RF signal received via the at least one measurement port.

18. The second measurement device according to claim 16,
the central processing unit being configured to output:
a) the RF signal received via the at least one measurement port via the at least one first external RF port to the first measurement device; and/or
b) the digitized RF signal via the first external control interface or via a first external data interface of the second measurement device to the first measurement device.

19. The second measurement device according to claim 12,
the second measurement device comprises a second external control interface configured for daisy-chaining the first external control interface with the second external control interface, wherein a third measurement device is connectable to the second external control interface;
and wherein the second measurement device optionally comprises at least one of:
a second external data interface configured for daisy-chaining the first external data interface with the second external data interface, wherein a third measurement device is connectable to the second external data interface;
a second LO port configured for daisy-chaining the first LO port to the second LO port, wherein a third measurement device is connectable the second LO port; and
a second external RF port configured for daisy-chaining the first external RF port to the second external RF port, wherein a third measurement device is connectable the second external RF port.

20. A set of measurement devices comprising a first measurement device and a second measurement device,
wherein the first measurement device comprises:
at least one measurement port configured to output and/or receive a radio frequency, RF, signal to and/or from the DUT;
a measurement unit connected to the at least one measurement port and being configured to measure the RF signal output and/or received at the at least one measurement port;
a display unit;
an user input unit for obtaining an user input;
an external control interface;
a central processing unit being connected to the measurement unit, the display unit, the user input unit and the external control interface,
whereas the central processing unit is configured:
to receive an obtained user input from the user input unit;
to receive the measured signal of the measurement unit; and
to output a display signal to the display unit for displaying the received measured signal;
wherein the second measurement device comprises:
at least one measurement port configured to output and/or receive a radio frequency, RF, signal to and/or from the DUT;
a measurement unit connected to the at least one measurement port and being configured to measure the RF signal output and/or received at the at least one measurement port;
a central processing unit being configured to control the measurement unit;
a first external control interface being configured to be connected to the external control interface of a first measurement device; and
wherein the external control interface of the first measurement device is connected to the first external control interface of the second measurement device; and
wherein the central processing unit of the first measurement device is configured to receive a user input from the user input unit and to forward the user input to the central processing unit of the second measurement device.
